(19) United States
(12) Patent Application Publication
(10) Pub. No.: US 2025/0034695 A1
(43) Pub. Date: Jan. 30, 2025

(54) APPARATUS FOR MANUFACTURING DISPLAY MODULE AND METHOD FOR MANUFACTURING DISPLAY MODULE

(71) Applicant: SAMSUNG DISPLAY CO., LTD., YONGIN-SI (KR)

(72) Inventors: JEONGWEON SEO, Yongin-si (KR); JUNYOUNG LEE, Yongin-si (KR); HYUK-HWAN KIM, Yongin-si (KR); JUNWOO YOU, Yongin-si (KR)

(21) Appl. No.: 18/658,213

(22) Filed: May 8, 2024

(30) Foreign Application Priority Data
Jul. 25, 2023 (KR) 10-2023-0096562

(51) Int. Cl. C23C 14/04; H10K 71/16

(52) U.S. Cl. CPC C23C 14/042; H10K 71/166

(57) ABSTRACT

An apparatus for manufacturing a display module includes a stage and a mask disposed over the stage. The mask includes a body, a frame that at least partially surrounds the body, and a plurality of bridges that are disposed between the body and the frame and that extend from the body toward the frame. A plurality of openings are defined between the bridges.

### CROSS-REFERENCE TO RELATED APPLICATIONS

This application claims priority under 35 U.S.C. § 119 to Korean Patent Application No. 10-2023-0096562, filed on Jul. 25, 2023 in the Korean Intellectual Property Office, the disclosure of which is incorporated by reference herein in its entireties.

### TECHNICAL FIELD

Embodiments of the present disclosure described herein relate to an apparatus for manufacturing a display module and a method for manufacturing a display module.

### DISCUSSION OF THE RELATED ART

In general, a display device includes a display module for displaying an image. The display module includes a display panel, a cover panel disposed under the display panel, and a window disposed on the display panel. The window protects the display panel from external impact and contamination. The cover panel has an electromagnetic shielding function, a heat radiating function, a light blocking function, and an impact absorbing function.

A mother panel is used when the display module is manufactured. The mother panel includes a plurality of unit panels. The above-described display panel is manufactured by providing cover panels on the unit panels and thereafter cutting the unit panels from the mother panel.

When the cover panels are disposed on the unit panels, a mask having openings corresponding to the cover panels is used. Portions of the mask between the openings are defined as ribs. The openings are relatively large, and therefore the ribs are relatively thin. The thin ribs may be easily bent by a small impact, and when the ribs are bent, the cover panels might not be normally manufactured.

### SUMMARY

An apparatus for manufacturing a display module includes a stage and a mask disposed over the stage. The mask includes a body, a frame that at least partially surrounds the body, and a plurality of bridges that are disposed between the body and the frame and that extend from the body toward the frame. A plurality of openings are defined between the bridges.

A method for manufacturing a display module includes placing a mother panel on a stage. A mask is placed on the mother panel. The mask includes a body, a frame that at least partially surrounds the body, and a plurality of bridges that extend from the body toward the frame and have openings defined between the bridges. A plurality of dams are formed by disposing a first resin in the openings, removing the mask, forming a cover layer by disposing a second resin in a first space defined by removal of the body and second spaces defined by removal of the bridges, and forming a cover panel by curing the dams and the cover layer.

A method for manufacturing a display module includes placing a mother panel on a stage. A dam is formed having a closed loop shape by disposing a first resin on the mother panel. The dam is cured using ultraviolet light. A cover layer is formed by providing a second resin in a space defined by the dam. The second resin is disposed to a height that is greater than a height of the dam, and the cover layer is thermally cured. The first resin includes a UV curable resin, and the second resin includes a thermosetting resin.

### BRIEF DESCRIPTION OF THE FIGURES

The above and other objects and features of the present disclosure will become apparent by describing in detail embodiments thereof with reference to the accompanying drawings.

FIG. 1 is an exploded perspective view of a display module manufacturing apparatus according to an embodiment of the present disclosure.

FIG. 2 is a plan view of a mother panel as viewed from above a first surface of the mother panel illustrated in FIG. 1.

FIG. 3 is a cross-sectional view taken along line I-I′ illustrated in FIG. 2.

FIG. 4 is a view illustrating a planar arrangement state of a stage, the mother panel, and supports illustrated in FIG. 1.

FIG. 5 is a view illustrating a planar arrangement state of a mask and a mask frame illustrated in FIG. 1.

FIG. 6 is an enlarged view of region AA illustrated in FIG. 5.

FIGS. 7 to 17 are views for explaining a method of manufacturing a display module according to an embodiment of the present disclosure.

FIG. 18 is a view for explaining a cutting process of FIG. 15 when a dummy layer is not used.

FIG. 19 is a view for explaining a cutting process of FIG. 15 when a dummy layer is used.

FIG. 20 is a view illustrating a mask according to a comparative example.

FIGS. 21 to 26 are views illustrating bridges according to various embodiments of the present disclosure.

FIGS. 27 to 31 are views for explaining a method of manufacturing a display module according to an embodiment of the present disclosure.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals may refer to identical components. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

As used herein, the term “and/or” includes all of one or more combinations defined by related components.

Terms such as first, second, and the like may be used to describe various components, but the components should not necessarily be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the present disclosure will be described with reference to the accompanying drawings.

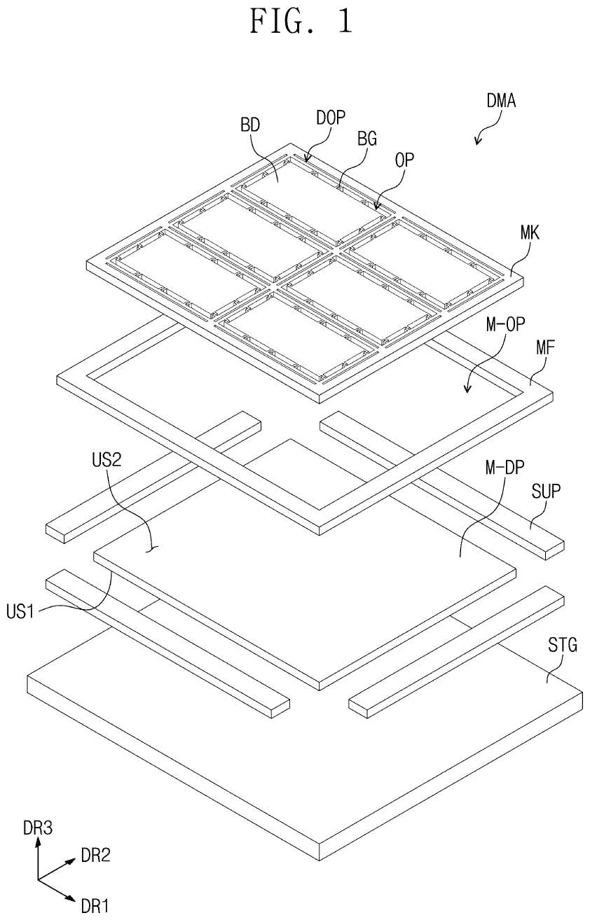

FIG. 1 is an exploded perspective view of a display module manufacturing apparatus according to an embodiment of the present disclosure.

In FIG. 1, a mother panel M-DP that is an object to be processed is illustrated together with the display module manufacturing apparatus DMA.

Referring to FIG. 1, the display module manufacturing apparatus DMA, according to an embodiment of the present disclosure, may include a stage STG, a plurality of supports SUP, a mask MK, and a mask frame MF.

The stage STG may have a rectangular shape with a pair of long sides extending parallel to each other in a first direction DR1 and a pair of short sides extending parallel to each other in a second direction DR2 crossing the first direction DR1. However, the shape of the stage STG is not necessarily limited thereto. The stage STG may have a plane defined by the first and second directions DR1 and DR2.

Hereinafter, a direction crossing the plane defined by the first and second directions DR1 and DR2 is defined as a third direction DR3. The third direction DR3 may be substantially perpendicular to the plane defined by the first and second directions DR1 and DR2. As used herein, the expression “when viewed from above the plane” or “in a plan view” may mean that it is viewed in the third direction DR3.

The mother panel M-DP, which is an object to be processed, may be disposed on the stage STG. The mother panel M-DP may be fixedly seated on the upper surface of the stage STG. A plurality of vacuum holes may be defined in the upper surface of the stage STG, and the mother panel M-DP may be fixed to the upper surface of the stage STG by vacuum pressure in the vacuum holes.

The mother panel M-DP may have a rectangular shape with a pair of long sides extending parallel to each other in the first direction DR1 and a pair of short sides extending parallel to each other in the second direction DR2. However, the shape of the mother panel M-DP is not necessarily limited thereto. The mother panel M-DP may have a plane defined by the first and second directions DR1 and DR2. Substantially, the mother panel M-DP may include a plurality of unit panels, and the configuration of the mother panel M-DP will be described below in detail.

The mother panel M-DP may have a first surface US1 and a second surface US2 opposite to the first surface US1. Each of the first and second surfaces US1 and US2 may have a plane defined by the first and second directions DR1 and DR2. In the display module manufacturing apparatus DMA, the first surface US1 may face downward, and the second surface US2 may face upward. A plurality of cover panels may be formed on the second surface US2 by the display module manufacturing apparatus DMA, and this process will be described below in detail.

The supports SUP may be disposed on the stage STG. The supports SUP may be disposed on the same plane as the mother panel M-DP. The supports SUP may be adjacent to the edge of the mother panel M-DP.

The supports SUP may include supports SUP extending in the first direction DR1 and supports SUP extending in the second direction DR2. The supports SUP extending in the first direction DR1 may be adjacent to the long sides of the mother panel M-DP that extend in the first direction DR1. The supports SUP extending in the second direction DR2 may be adjacent to the short sides of the mother panel M-DP that extend in the second direction DR2.

The mask MK and the mask frame MF may be disposed over the stage STG. The mask MK may be disposed on the mother panel M-DP. The mask frame MF may be disposed on the supports SUP. Accordingly, the mother panel M-DP and the supports SUP may be disposed between the mask MK and the stage STG and between the mask frame MF and the stage STG.

The first surface US1 of the mother panel M-DP may face toward the stage STG and may face the stage STG. The second surface US2 of the mother panel M-DP may face toward the mask MK and may face the mask MK.

The mask MK may have a rectangular shape with a pair of long sides extending parallel to each other in the first direction DR1 and a pair of short sides extending parallel to each other in the second direction DR2. However, the shape of the mask MK is not necessarily limited thereto. The mask MK may include a metal/metal alloy. For example, the mask MK may include Invar or stainless steel.

The mask MK may include a plurality of bodies BD. The bodies BD may be arranged in the first direction DR1 and the second direction DR2. Although six bodies BD arranged in three rows (corresponding to the first direction DR1) and two columns (corresponding to the second direction DR2) are illustrated as an example, the number and arrangement of bodies BD are not necessarily limited to the state illustrated in FIG. 1.

A plurality of openings OP may be defined around each of the bodies BD. The openings OP may at least partially surround the body BD. Furthermore, a plurality of dummy openings DOP may be defined in the mask MK so as to be located outward of the openings OP. Functions of the openings OP and the dummy openings DOP will be described below in detail.

The mask frame MF may have a frame shape. The outer edge of the mask frame MF may have a rectangular shape with a pair of long sides extending parallel to each other in the first direction DR1 and a pair of short sides extending parallel to each other in the second direction DR2. However, the shape of the mask frame MF is not necessarily limited thereto.

The mask frame MF may have an opening M-OP defined therein. The opening M-OP may have a shape corresponding to the mask MK. The mask MK may be disposed in the opening M-OP. Accordingly, the mask frame MF may at least partially surround the mask MK. The mask frame MF may include a metal/metal alloy. For example, the mask frame MF may include aluminum (Al).

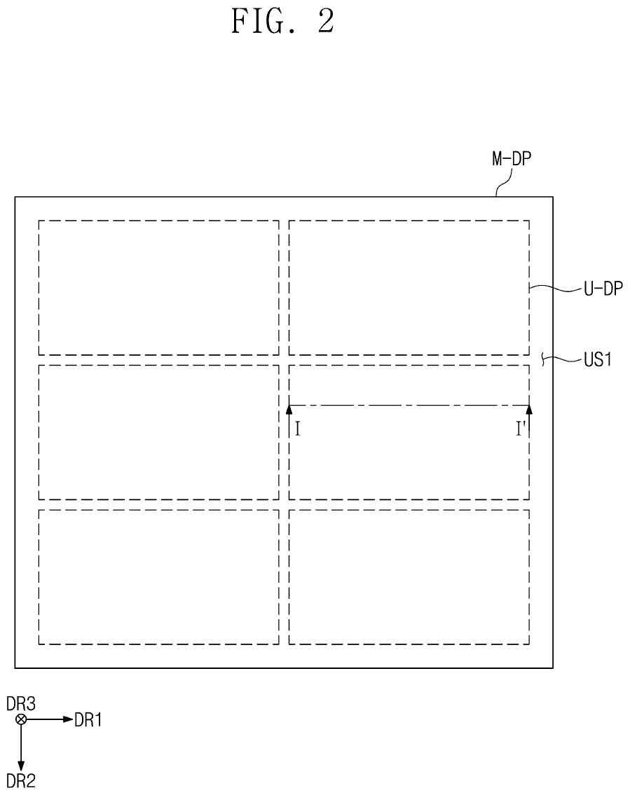

FIG. 2 is a plan view of the mother panel as viewed from above the first surface of the mother panel illustrated in FIG. 1.

Referring to FIG. 2, the mother panel M-DP may include the plurality of unit panels U-DP. For example, the unit panels U-DP are illustrated by dotted lines. Each of the unit panels U-DP may be defined as a display panel for displaying an image.

The unit panels U-DP may be cut after the cover panels overlapping the respective unit panels U-DP are disposed on the second surface US2. The edges of the unit panels U-DP illustrated by the dotted lines in FIG. 2 may define cutting lines in a cutting process that will be described below. The unit panels U-DP may be separated from one another by cutting the mother panel M-DP along the edges of the unit panels U-DP defined as the cutting lines. This process will be described below in detail.

Each of the unit panels U-DP may have a rectangular shape with a pair of long sides extending in the first direction DR1 and a pair of short sides extending in the second direction DR2. However, the shape of the unit panel U-DP is not necessarily limited thereto.

Referring to FIGS. 1 and 2, when viewed from above the plane, the unit panels U-DP may overlap the bodies BD illustrated in FIG. 1, respectively. Accordingly, the unit panels U-DP may be arranged in the first direction DR1 and the second direction DR2. Although six unit panels U-DP arranged in three rows and two columns are illustrated as an example, the number and arrangement of unit panels U-DP are not necessarily limited thereto.

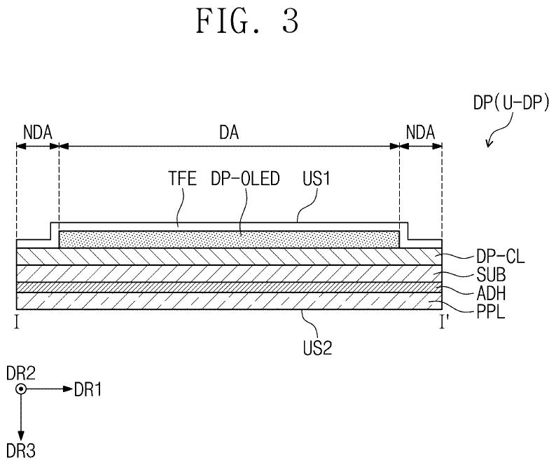

FIG. 3 is a cross-sectional view taken along line I-I′ illustrated in FIG. 2.

Hereinafter, in FIG. 3, the unit panel U-DP is referred to as the display panel DP.

Referring to FIGS. 2 and 3, in an embodiment of the present disclosure, the display panel DP may be an emissive display panel, but is not necessarily particularly limited thereto. For example, the display panel DP may be an organic light emitting diode (OLED) display panel or a quantum-dot light emitting display panel. An emissive layer of the organic light emitting diode display panel may include an organic light emitting material. An emissive layer of the quantum-dot light emitting display panel may include quantum dots and quantum rods. Hereinafter, it will be exemplified that the display panel DP is an organic light emitting diode display panel.

The display panel DP may include a substrate SUB, a circuit element layer DP-CL disposed on the substrate SUB, a display element layer DP-OLED disposed on the circuit element layer DP-CL, a thin-film encapsulation layer TFE disposed on the display element layer DP-OLED, a panel protection layer PPL disposed under the substrate SUB, and an adhesive layer ADH disposed between the substrate SUB and the panel protection layer PPL. The substrate SUB, the circuit element layer DP-CL, the display element layer DP-OLED, the thin film encapsulation layer TFE, and the panel protection layer PPL may be defined as components of the mother panel M-DP.

The substrate SUB may include a display region DA and a non-display region NDA at least partially surrounding the display region DA. The substrate SUB may include glass. However, without necessarily being limited thereto, the substrate SUB may include a flexible plastic material such as polyimide. The display element layer DP-OLED may be disposed on the display region DA.

A plurality of pixels may be disposed in the display region DA. Each of the pixels may include a light emitting element that is connected to transistors disposed in the circuit element layer DP-CL and is disposed in the display element layer DP-OLED.

The thin film encapsulation layer TFE may be disposed on the circuit element layer DP-CL and may cover the display element layer DP-OLED. The thin film encapsulation layer TFE may include inorganic layers and an organic layer between the inorganic layers. The inorganic layers may protect the pixels from moisture/oxygen. The organic layer may protect the pixels from foreign matter such as dust particles.

The panel protection layer PPL may protect the bottom of the substrate SUB. The panel protection layer PPL may include a flexible plastic material. For example, the panel protection layer PPL may include polyimide or polyethylene terephthalate.

The adhesive layer ADH may be disposed between the substrate SUB and the panel protection layer PPL. The substrate SUB and the panel protection layer PPL may be bonded to each other by the adhesive layer ADH. The adhesive layer ADH may include a pressure sensitive adhesive (PSA). However, the type of adhesive is not necessarily limited thereto.

Likewise to the mother panel M-DP, the display panel DP may include a first surface US1 and a second surface US2. The first surface US2 may be defined by the upper surface of the thin film encapsulation layer TFE, and the second surface US2 may be defined by the lower surface of the panel protection layer PPL. Accordingly, the substrate SUB, the circuit element layer DP-CL, and the display element layer DP-OLED may be disposed between the first surface US1 and the second surface US2.

The display element layer DP-OLED may be disposed on the substrate SUB facing toward the first surface US1. Because the unit panels U-DP overlap the respective bodies BD as described above, the display element layer DP-OLED, when viewed from above the plane, may overlap a corresponding body BD among the bodies BD.

In FIG. 3, the first surface US1 has a step between the display region DA and the non-display region NDA. However, in the mother panel M-DP, the first surface US1 is illustrated as being flat.

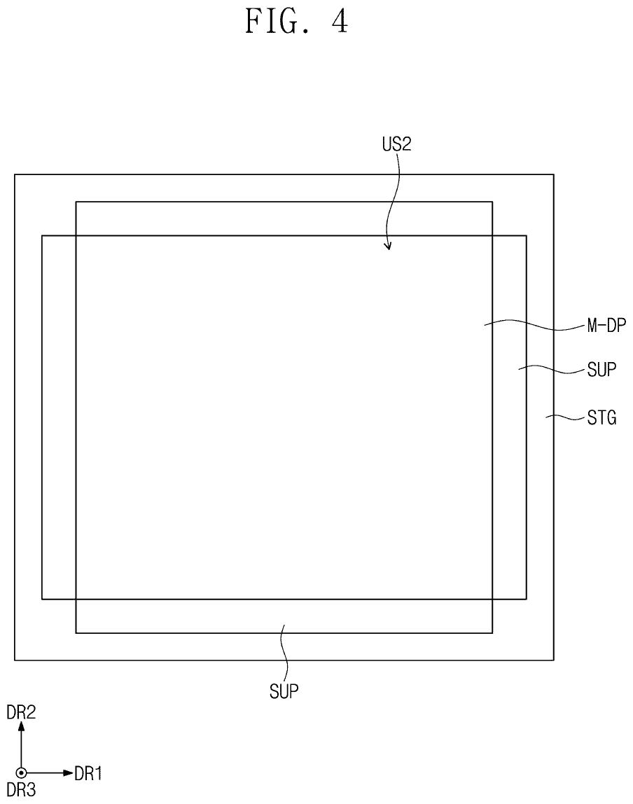

FIG. 4 is a view illustrating a planar arrangement state of the stage, the mother panel, and the supports illustrated in FIG. 1.

Referring to FIG. 4, when the mother panel M-DP and the supports SUP are disposed on the stage STG, the mother panel M-DP and the supports SUP may be disposed inward of the edge of the stage STG. The mother panel M-DP may be disposed such that the second surface US2 thereof faces upward.

The supports SUP extending in the first direction DR1 and facing each other in the second direction DR2 may make contact with the long sides of the mother panel M-DP that extend parallel to each other in the first direction DR1. The supports SUP extending in the second direction DR2 and facing each other in the first direction DR1 may make contact with the short sides of the mother panel M-DP that extend in the first direction DR1.

The long sides and the short sides of the mother panel M-DP may define the edge of the mother panel M-DP. The supports SUP may make contact with the edge of the mother panel M-DP. The edge of the mother panel M-DP may be supported by the supports SUP, and the position of the mother panel M-DP may be fixed accordingly.

Although the supports SUP are disposed at all of the four sides of the mother panel M-DP, embodiments of the present disclosure are not necessarily limited thereto. For example, only the two supports SUP extending in the first direction DR1 may make contact with the long sides of the mother panel M-DP. Alternatively, only the two supports SUP extending in the second direction DR2 may make contact with the short sides of the mother panel M-DP.

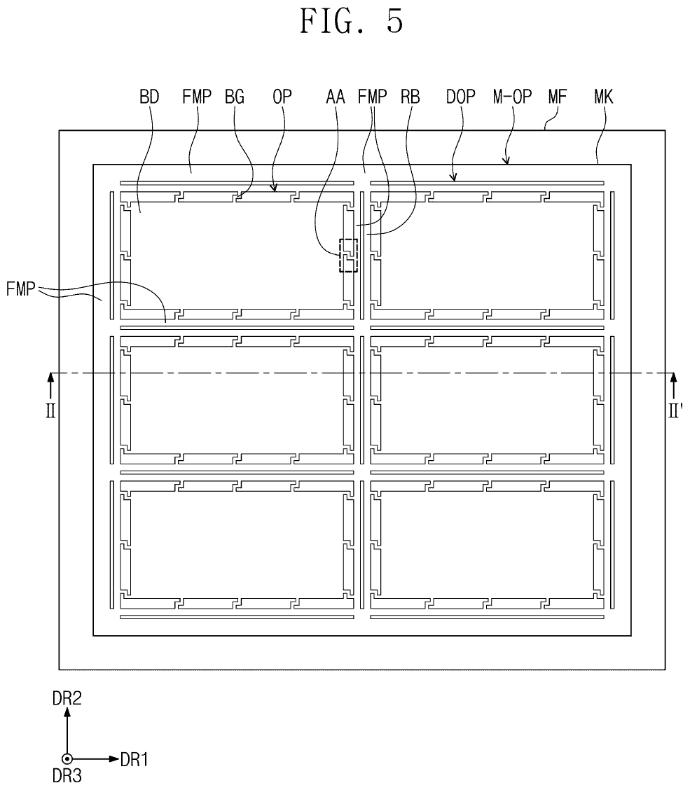

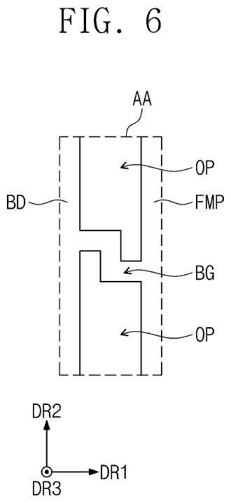

FIG. 5 is a view illustrating a planar arrangement state of the mask and the mask frame illustrated in FIG. 1. FIG. 6 is an enlarged view of region AA illustrated in FIG. 5.

Referring to FIG. 5, the mask MK may be disposed in the opening M-OP of the mask frame MF. Accordingly, the mask frame MF may at least partially surround the edge of the mask MK. An inner surface of the mask frame MF that defines the opening M-OP may make contact with the edge of the mask MK. Accordingly, the mask MK may be easily fixed to the mask frame MF.

The mask MK may include the plurality of bodies BD, a frame FMP, and a plurality of bridges BG. Each of the bodies BD may have a plane defined by the first and second directions DR1 and DR2.

The frame FMP may be defined as a portion of the mask MK that surrounds the bodies BD. For example, the frame FMP may be defined as a portion of the mask MK between the bodies BD. Furthermore, the frame FMP may be defined as a portion of the mask MK between the edge of the mask MK and the edges of the bodies BD that face toward the edge of the mask MK.

The bridges BG may be disposed between each of the bodies BD and the frame FMP. The bridges BG may be disposed along the edge of the body BD. For example, the bridges BG may at least partially surround the body BD. The frame FMP may be defined as a portion of the mask MK that is disposed outward of the bridges BG and that surrounds the body BD. Portions of the frame FMP between the bodies BD may be defined as ribs RB.

The bridges BG may extend from each of the bodies BD toward the frame FMP. Although twelve bridges BG extending from the body BD are illustrated as an example, more bridges BG may extend from the body BD.

The bridges BG may connect the bodies BD and the frame FMP. For example, the bodies BD, the bridges BG, and the frame FMP may be integrally formed. However, without necessarily being limited thereto, the bridges BG may be separately manufactured and may be connected to the bodies BD and the frame FMP. For example, the bridges BG may be connected to the bodies BD and the frame FMP by a welding process.

The plurality of openings OP may be defined between the bridges BG. Substantially, the openings OP may be defined between the bridges BG, the bodies BD, and the frame FMP. The openings OP may be arranged along each of the bodies BD.

The bodies BD may have a pair of long sides extending parallel to each other in the first direction DR1 and a pair of short sides extending parallel to each other in the second direction DR2. Openings OP defined along the long sides of the body BD may extend in the first direction DR1, and openings OP defined along the short sides of the body BD may extend in the second direction DR2.

The plurality of dummy openings DOP may be defined in the frame FMP. The dummy openings DOP may be disposed outward of the bridges BG and the openings OP. The dummy openings DOP may at least partially surround the bridges BG. The dummy openings DOP may be adjacent to the bridges BG and the openings OP.

The dummy openings DOP may extend along the long sides and the short sides of the body BD. Dummy openings DOP adjacent to the long sides of the body BD may extend in the first direction DR1, and dummy openings DOP adjacent to the short sides of the body BD may extend in the second direction DR2.

Referring to FIGS. 5 and 6, each of the bridges BG may have a bent shape. For example, in FIG. 6, the bridge BG may extend in the first direction DR1, the second direction DR2, and the first direction DR1 and may be bent twice. The bridge BG may have a width of 0.5 mm to 1.5 mm. The width of the bridge BG may be defined as a numerical value measured in a direction crossing the extension direction of the bridge BG.

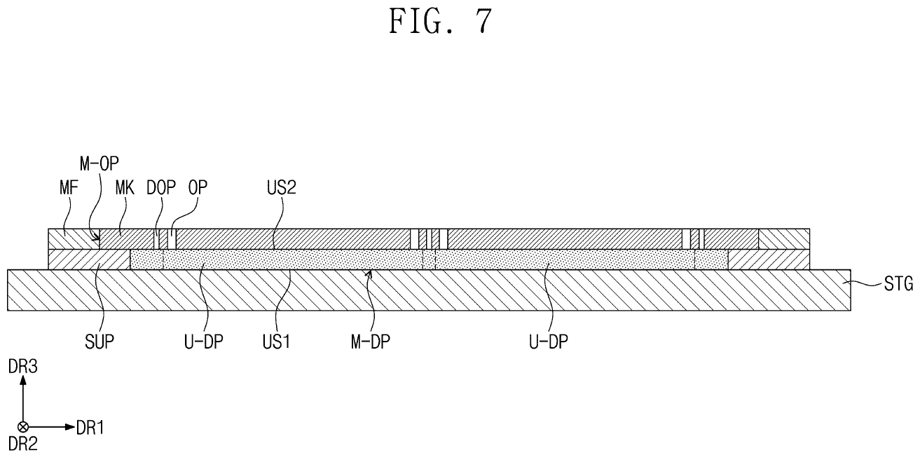

FIGS. 7 to 17 are views for explaining a method of manufacturing a display module according to an embodiment of the present disclosure. FIG. 7 is a cross-sectional view taken along line II-II′ illustrated in FIG. 5.

In FIG. 7, sections of the stage STG, the mother panel M-DP, the supports SUP, the mask MK, and the mask frame MF are illustrated together. The unit panels U-DP are illustrated by dotted lines.

Referring to FIG. 7, the mother panel M-DP including the unit panels U-DP may be disposed on the stage STG, and the mask MK may be disposed on the mother panel M-DP. As described above, the supports SUP may make contact with the edge of the mother panel M-DP, and the mother panel M-DP may be fixed accordingly. In addition, the mask MK may be disposed in the opening M-OP of the mask frame MF and may be fixed accordingly.

When viewed from above the plane, the openings OP may be disposed inward of the edge of each of the unit panels U-DP. When viewed from above the plane, the dummy openings DOP may be disposed outward of the edge of the unit panel U-DP. Accordingly, when viewed from above the plane, the edge of the unit panel U-DP may be disposed between the openings OP and the dummy openings DOP adjacent to the edge of the unit panel U-DP.

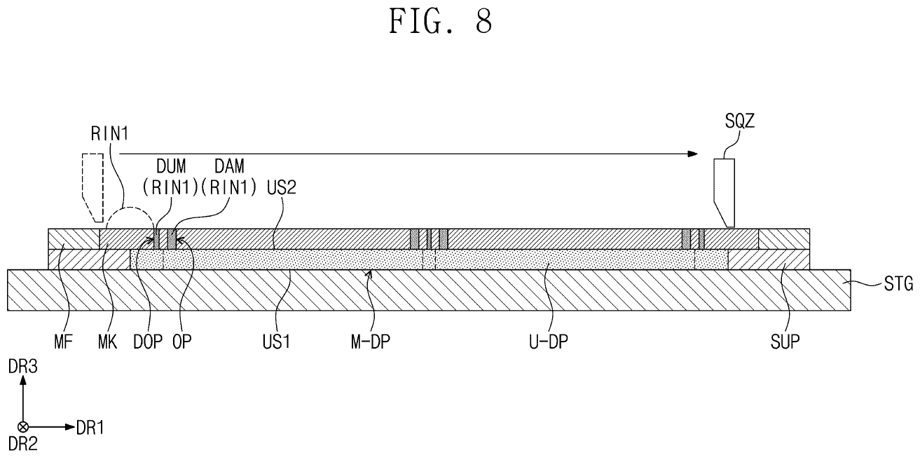

Referring to FIG. 8, a squeegee SQZ may be disposed on the mask MK. In addition, a first resin RIN1 may be disposed on the mask MK. The first resin RIN1 may be disposed on the upper surface of the mask MK that is adjacent to one side of the mask MK.

The squeegee SQZ may move in the first direction DR1 to push the first resin RIN1 from the one side of the mask MK to an opposite side of the mask MK. When the squeegee SQZ pushes the first resin RIN1, the first resin RIN1 may be disposed in the openings OP and the dummy openings DOP. This process using the mask MK and the squeegee SQZ may be defined as a metal mask screen printing process.

The first resin RIN1 may be disposed in the openings OP to form a plurality of dams DAM. The first resin RIN1 may be disposed in the dummy openings DOP to form a plurality of dummy layers DUM. Accordingly, the dams DAM and the dummy layers DUM may be disposed on the mother panel M-DP. The dams DAM may be disposed on the unit panel U-DP so as to be adjacent to the edge of the unit panel U-DP. The dummy layers DUM may be disposed outward of the unit panel U-DP.

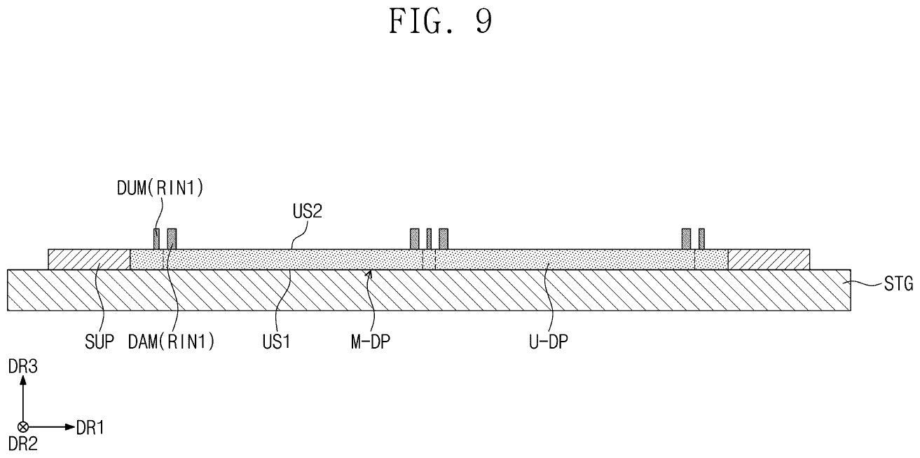

Referring to FIG. 9, the mask MK and the mask frame MF may be removed from the mother panel M-DP. Accordingly, the dams DAM and the dummy layers DUM may remain on the mother panel M-DP.

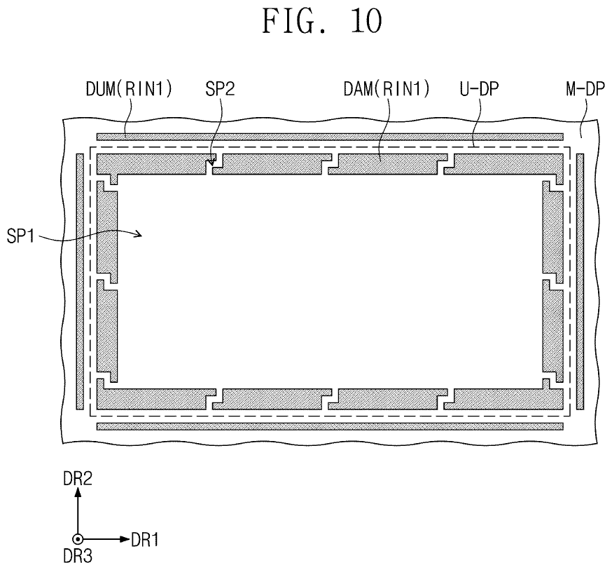

FIG. 10 is a plan view illustrating dams and dummy layers disposed on one unit panel illustrated in FIG. 9.

In FIG. 10, the edge of the unit panel U-DP is illustrated by a dotted line. The edge of the unit panel U-DP may function as a cutting line in a cutting process that will be described below.

Referring to FIG. 10, the dams DAM may be arranged along the edge of the unit panel U-DP. The dams DAM may be disposed inward of the edge of the unit panel U-DP. The dams DAM may have a shape corresponding to the openings OP.

The dams DAM adjacent to long sides of the unit panel U-DP that extend in the first direction DR1 may extend in the first direction DR1 and may be arranged in the first direction DR1. The dams DAM adjacent to short sides of the unit panel U-DP that extend in the second direction DR1 may extend in the second direction DR2 and may be arranged in the second direction DR2.

The first resin RIN1 may be disposed in the openings OP and the dummy openings DOP and may be blocked by the body BD and the bridges BG. When the mask MK is removed, a first space SP1 may be defined in a region overlapping the body BD. For example, the first space SP1 may be defined as a space formed by removal of the body BD. Furthermore, the first space SP1 may be defined as a space surrounded by the dams DAM.

When the mask MK is removed, second spaces SP2 may be defined in regions overlapping the bridges BG. For example, the second spaces SP2 may be defined as spaces formed by removal of the bridges BG. Furthermore, each of the second spaces SP2 may be defined as a space between two dams DAM adjacent to each other.

The dummy layers DUM may be located outward of the unit panel U-DP and may be adjacent to the four sides of the unit panel U-DP, respectively. Although four dummy layers DUM adjacent to the four sides of the unit panel U-DP are illustrated as an example, the number of dummy layers DUM is not necessarily limited thereto, and more than four dummy layers DUM may be provided.

The dummy layers DUM adjacent to the long sides of the unit panel U-DP that extend in the first direction DR1 may extend in the first direction DR1. The dummy layers DUM adjacent to the short sides of the unit panel U-DP that extend in the second direction DR2 may extend in the second direction DR2.

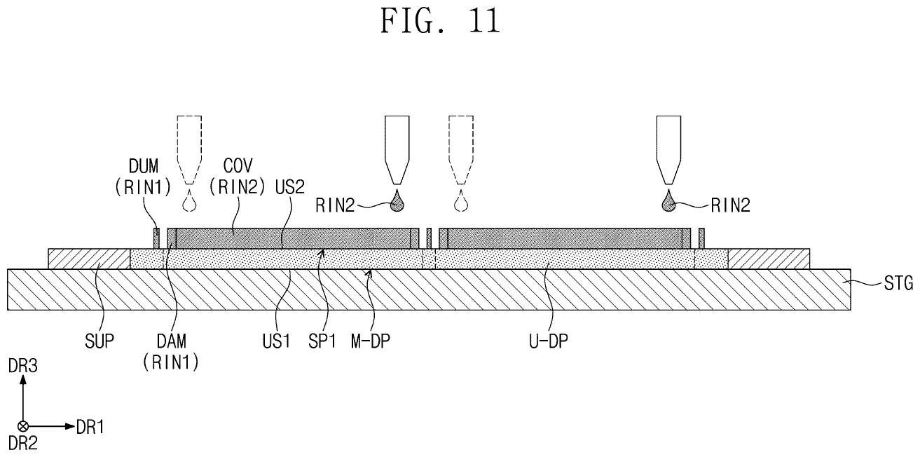

Referring to FIG. 11, a nozzle NZ may be disposed over the mother panel M-DP, and a second resin RIN2 may be dispensed from the nozzle NZ toward the mother panel M-DP. The second resin RIN2 may be disposed on the mother panel M-DP. The second resin RIN2 may be disposed in the first spaces SP1. For example, the second resin RIN2 may be disposed on each of the unit panels U-DP.

A process of providing a resin on a process target using the nozzle NZ may be defined as a dispensing printing process. An inkjet method, a jet valve method, and a slit coating method may be used as the dispensing printing process.

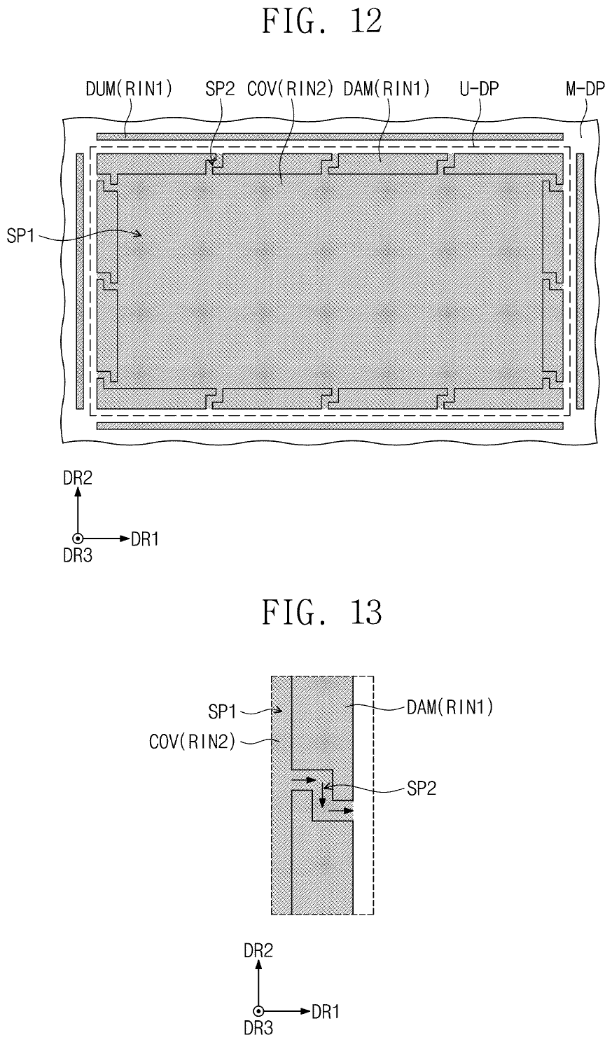

FIG. 12 is a plan view illustrating a state in which the second resin is disposed on one unit panel illustrated in FIG. 11. FIG. 13 is an enlarged view illustrating the second resin disposed in one second space illustrated in FIG. 12.

Referring to FIGS. 12 and 13, after the second resin RIN2 is disposed in the first space SP1, the second resin RIN2 may be disposed from the first space SP1 to the second spaces SP2 depending on a flow of the second resin RIN2. When the second resin RIN2 is disposed in the second spaces SP2, the second resin RIN2 might not overflow the dams DAM. For example, the second resin RIN2 might not be disposed outside the second spaces SP2.

For example, the second resin RIN2 may have a viscosity of 1000 cps to 100000 cps, for example, a viscosity of 35000 cps. As the viscosity of the second resin RIN2 is increased, the fluidity of the second resin RIN2 may be decreased. Because each of the bridges BG has a width of 0.5 mm to 1.5 mm as described above, each of the second spaces SP2 may also have a relatively small width of 0.5 mm to 1.5 mm.

Referring to FIG. 13, when the second resin RIN2 has high viscosity (e.g., 35000 cps) and the second space SP2 has a relatively small width of 0.5 mm to 1.5 mm, the second resin RIN2 may be disposed up to the second space SP2 and might not overflow the dams DAM. In addition, because each of the bridges BG has a bent shape, the second space SP2 may also have a bent shape.

The second space SP2 having a bent shape may obstruct the flow of the second resin RIN2. For example, the fluidity of the second resin RIN2 having high viscosity may be further decreased in the second space SP2. Accordingly, the second resin RIN2 having high viscosity and low fluidity may be disposed only in the second space SP2 without being disposed outside the second space SP2.

Referring to FIGS. 11 and 12, the second resin RIN2 may be disposed in the first and second spaces SP1 and SP2 to form cover layers COV. The dams DAM and the cover layers COV may be disposed inward of the edges of the unit panels U-DP. The cover layer COV and the dams DAM on each of the unit panels U-DP may make contact with each other.

Depending on the above-described processes, the first and second resins RIN1 and RIN2 may be directly applied to the second surface US2 of the mother panel M-DP to form the dams DAM and the cover layers COV. The first resin RIN1 and the second resin RIN2 may include the same material. The first resin RIN1 and the second resin RIN2 may include a thermosetting resin.

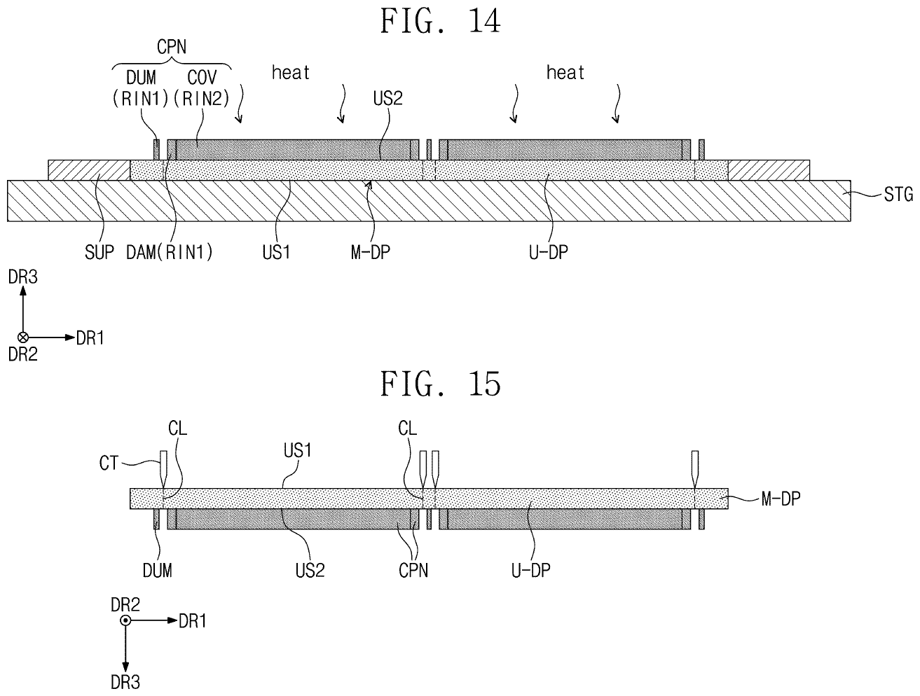

Referring to FIG. 14, the first resin RIN1 and the second resin RIN2 may be cured by the same method. For example, the dams DAM, the dummy layers DUM, and the cover layers COV may be cured by heat applied to the dams DAM, the dummy layers DUM, and the cover layers COV. For example, the dams DAM, the dummy layers DUM, and the cover layers COV may be thermally cured.

A thermosetting resin may shrink during thermal curing. The first resin RIN1 and the second resin RIN2 may have the same shrinkage because the first resin RIN1 and the second resin RIN2 include the same material. Accordingly, the dummy layers DUM and the cover layers COV formed of the first resin RIN1 and the second resin RIN2 may have the same thickness even though thermally cured.

The cured dummy layers DUM and the curved cover layers COV may form cover panels CPN. The cover panels CPN may be disposed on the mother panel M-DP. The cover panels CPN may be disposed on the unit panel U-DP, respectively. The cover panels CPN may be disposed on the second surface US2. Each of the cover panels CPN may include the cover layer COV and the dams DAM making contact with the cover layer COV.

The first resin RIN1 and the second resin RIN2 may include a polymer resin, graphite, and carbon fibers. The polymer resin may include silicone or rubber. The graphite and the carbon fibers may be dispersed in the polymer resin in the form of solid particles as fillers. The graphite particles may have a size of 5 micrometers to 30 micrometers. The carbon fiber particles may have a size of 50 micrometers to 200 micrometers.

The graphite may have a heat radiating function. The carbon fibers may be black in color and may have a light blocking function and an electromagnetic shielding function. The polymer resin may have an impact absorbing function.

Depending on the constituent materials of the first resin RIN1 and the second resin RIN2, each of the cover panels CPN may have a heat radiating function, a light blocking function, an electromagnetic shielding function, and an impact absorbing function. The cover panels CPN may be disposed on the unit panels U-DP by directly coating the second surfaces US2 of the unit panels U-DP with the first resin RIN1 and the second resin RIN2 and curing the first resin RIN1 and the second resin RIN2.

When the cover panels CPN are not formed of the above-described first and second resins RIN1 and RIN2, layers having a heat radiating function, a light blocking function, an electromagnetic shielding function, and an impact absorbing function have to be separately disposed on the unit panels U-DP. For example, a light blocking film that is black in color is disposed on each of the unit panels U-DP, a cushion layer that absorbs an external impact is disposed on the light blocking film, and a metal layer that shields electromagnetism and has a heat radiating function is disposed on the cushion layer.

Because these layers are stacked on the unit panels U-DP, a plurality of processes may be required, and therefore process efficiency may be lowered. Furthermore, separate adhesive layers for bonding the layers may be required.

However, in the embodiment of the present disclosure, the cover panels CPN may be formed by directly coating the second surfaces US2 of the unit panels U-DP with the first and second resins RIN1 and RIN2. Accordingly, the process may be simplified.

Referring to FIG. 15, the mother panel M-DP may be inverted in the third direction DR3. Accordingly, the first surface US1 may face upward, and the second surface US2 may face downward. A cutting tool CT may be disposed on the mother panel M-DP. The cutting tool CT may be disposed on the first surface US1. For example, the cutting tool CT may be a knife.

The edges of the unit panels U-DP illustrated by dotted lines may define cutting lines CL of the mother panel M-DP. In each of the unit panels U-DP, the cutting line CL may be defined between the dummy layers DUM and the cover panel CPN.

The cutting tool CT may move along the cutting lines CL while rotating and may cut the unit panels U-DP from the mother panel M-DP. Accordingly, the unit panels U-DP may be separated from one another. The cutting tool CT may apply pressure to the second surface US2 to form cracks on the second surface US2, and thus the mother panel M-DP may be cut into the unit panels U-DP.

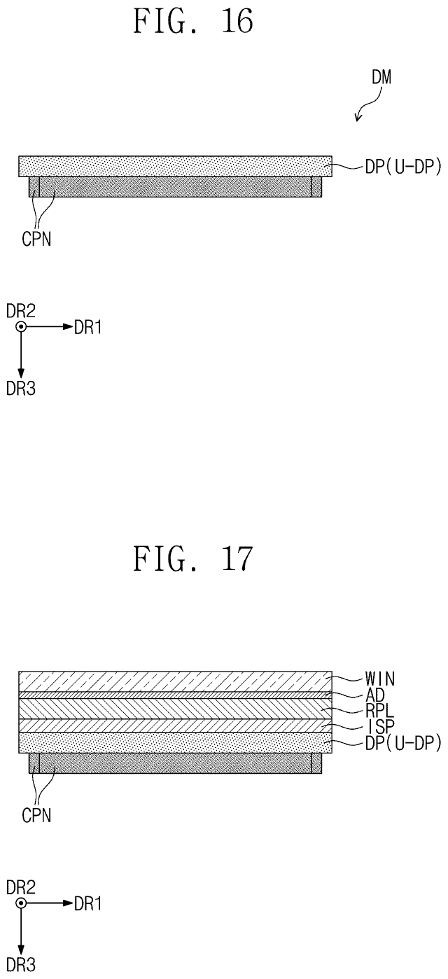

FIG. 16 is a view illustrating one unit panel illustrated in FIG. 15 and a cover panel coated on the unit panel. FIG. 17 is a view illustrating components disposed on the unit panel illustrated in FIG. 16.

Hereinafter, in FIGS. 16 and 17, the unit panel U-DP is referred to as the display panel DP.

Referring to FIG. 16, the cover panel CPN having a heat radiating function, a light blocking function, an electromagnetic shielding function, and an impact absorbing function may be disposed under the display panel DP. The display panel DP and the cover panel CPN may be components of the display module DM.

Referring to FIG. 17, an input sensing unit ISP, an anti-reflection layer RPL, and a window WIN may be sequentially stacked on the display panel DP. The input sensing unit ISP may be directly disposed on the display panel DP, and the anti-reflection layer RPL may be directly disposed on the input sensing unit ISP. An adhesive layer AD may be disposed between the window WIN and the anti-reflection layer RPL, and the window WIN and the anti-reflection layer RPL may be bonded to each other by the adhesive layer AD.

The display module DM may be manufactured by sequentially stacking the input sensor ISP, the anti-reflection layer RPL, and the window WIN on the display panel DP. Accordingly, the display module DM may include the display panel DP, the cover panel CPN, the input sensing unit ISP, the anti-reflection layer RPL, and the window WIN.

The input sensing unit ISP may include a plurality of sensors for sensing an external input. For example, the input sensing unit ISP may sense the external input in a capacitive type. However, a sensing method of the input sensing unit ISP is not necessarily limited thereto. The input sensing unit ISP may be directly formed on the display panel DP when the display module DM is manufactured.

The anti-reflection layer RPL may be disposed on the input sensing unit ISP. The anti-reflection layer RPL may be directly formed on the input sensing unit ISP when the display module DM is manufactured. The anti-reflection layer RPL may be defined as a film for preventing reflection of external light. The anti-reflection layer RPL may decrease the reflectance of external light incident toward the display panel DP from above the display device DD.

When external light travelling toward the display panel DP is reflected from the display panel DP and provided back to a user, the user may visually recognize the external light as in a mirror (e.g., the user may see reflection). To prevent such a phenomenon, the anti-reflection layer RPL may include a plurality of color filters that display the same colors as those of pixels of the display panel DP.

The color filters may filter the external light into the same colors as those of the pixels. In this case, the external light might not be visible to the user. However, without necessarily being limited thereto, the anti-reflection layer RPL may include a phase retarder and/or a polarizer to decrease the reflectance of the external light.

For example, the input sensing unit ISP may be directly formed on the display panel DP, and the anti-reflection layer RPL may be directly formed on the input sensing unit ISP. However, embodiments of the present disclosure are not necessarily limited thereto. For example, the input sensing unit ISP may be separately manufactured and may be attached to the display panel DP by an adhesive layer, and the anti-reflection layer RPL may be separately manufactured and may be attached to the input sensing unit ISP by an adhesive layer.

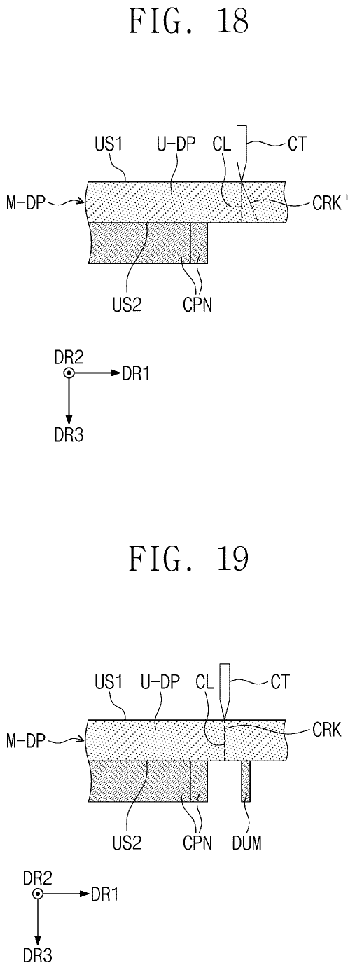

FIG. 18 is a view for explaining the cutting process of FIG. 15 when the dummy layer is not used. FIG. 19 is a view for explaining the cutting process of FIG. 15 when the dummy layer is used.

FIGS. 18 and 19 illustrate a portion of the mother panel M-DP adjacent to one side of the cover panel CPN.

Referring to FIG. 18, the dummy layer DUM might not be used. The cutting tool CT may be disposed on the first surface US1. The cutting tool CT may apply pressure to the mother panel M-DP along the cutting line CL to form a crack CRK′ in the mother panel M-DP. However, the oblique crack CRK′ may be generated due to stress asymmetry between the portion of the mother panel M-DP on which the cover panel CPN is disposed and the portion of the mother panel M-DP on which the cover panel CPN is not disposed.

The cover panel CPN disposed under the mother panel M-DP may serve as a support that supports the portion of the mother panel M-DP that overlaps the cover panel CPN. However, the cover panel CPN is not disposed under the portion of the mother panel M-DP that does not overlap the cover panel CPN, and therefore a component serving as a support does not exist. In this case, depending on the above-described stress asymmetry phenomenon, the oblique crack CRK′ may be generated when the cutting tool CT applies pressure to the cutting line CL. Accordingly, the cutting process might not be normally performed.

Referring to FIG. 19, the cover panel CPN may support the portion of the mother panel M-DP on the left side with respect to the cutting line CL, and the dummy layer DUM may support the portion of the mother panel M-DP on the right side with respect to the cutting line CL. In this case, when the cutting tool CT applies pressure to the cutting line CL, a crack CRK extending in the third direction DR3 may be normally formed along the cutting line CL. Accordingly, the cutting process may be normally performed due to the dummy layer DUM.

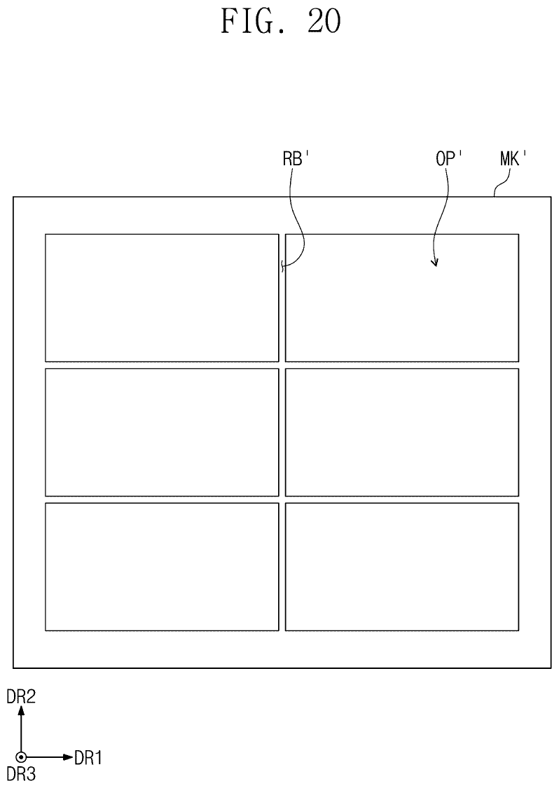

FIG. 20 is a view illustrating a mask according to a comparative example.

FIG. 20 is a plan view of the mask according to the comparative example.

Referring to FIG. 20, a plurality of openings OP′ may be defined in the mask MK′ according to the comparative example. Portions of the mask MK′ between the openings OP′ may be defined as ribs RB′. Unlike the mask MK illustrated in FIG. 5, the mask MK′ might not include the bodies BD and the bridges BG.

Cover panels may be formed through a mask screen printing process using the mask MK′ illustrated in FIG. 20. For example, similarly to that illustrated in FIG. 8, a squeegee SQZ may push a resin RIN disposed on the mask MK′, and the resin RIN may be disposed on a mother panel M-DP through the openings OP′. The resin RIN disposed in the openings OP′ may be cured to form cover panels CPN.

Because the large openings OP′ are defined in the mask MK′, the widths of the ribs RB′ may be particularly thin. Therefore, the ribs RB′ may be vulnerable to an impact. The ribs RB′ may be curved due to impact with an external object when the mask MK′ is moved. When the ribs RB′ are curved, the resin RIN might not be disposed on a predetermined region. Therefore, the cover panels CPN may have a defect.

Referring to FIGS. 5 and 20, unlike the mask MK′, the mask MK might not include the large openings OP′ and may include the bodies BD and the bridges BG. The body BD and the bridges BG may be connected to the ribs RB.

Because the bridges BG are connected to the ribs RB, the bridges BG may serve to more firmly fix the ribs RB. Accordingly, the ribs RB might not be deformed even though an external impact is applied to the mask MK.

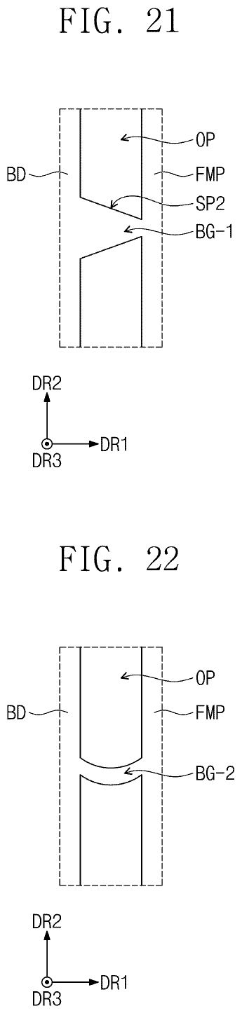

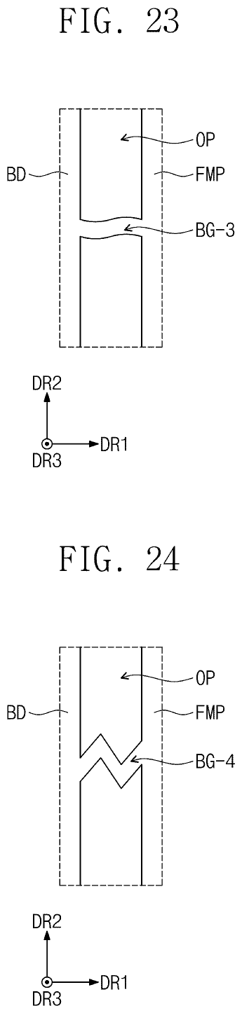

FIGS. 21 to 26 are views illustrating bridges according to various embodiments of the present disclosure.

FIGS. 21 to 26 illustrate enlarged views corresponding to FIG. 6, and the following description will be focused on differences between the bridge BG illustrated in FIG. 6 and the bridges BG-1 to BG-6 illustrated in FIGS. 21 to 26. Thus, to the extent that an element is not described in detail with respect to this figure, it may be understood that the element is at least similar to a corresponding element that has been described elsewhere within the present disclosure

Referring to FIG. 21, the bridge BG-1 may have a trapezoidal shape from a body BD to a frame FMP. Accordingly, the width of the bridge BG-1 in the second direction DR2 may be gradually decreased in the first direction DR1. For example, the width of the bridge BG-1 may be gradually decreased toward the outside.

When the mask MK is removed, as described above with reference to FIGS. 10 to 13, a second space SP2 may be formed in the portion where the bridge BG-1 is disposed. The reference numeral “SP2” for the second space SP2 illustrated in FIG. 21 is illustrated under the assumption that the bridge BG-1 is removed.

Because the bridge BG-1 has a trapezoidal shape, the second space SP2 may also have a trapezoidal shape toward the frame FMP. Accordingly, the width of the second space SP2 may also be gradually decreased toward the outside. For example, the exit of the second space SP2 toward the frame FMP may be narrowed.

When a second resin RIN2 is disposed into the second space SP2 from a first space SP1, the fluidity of the second resin RIN2 may be decreased because the exit of the second space SP2 is narrowed. Accordingly, the second resin RIN2 might not overflow out of the second space SP2.

Referring to FIGS. 22 to 24, the bridge BG-2 may have a curved shape from a body BD toward a frame FMP. The bridge BG-3 may have a wave shape extending in a curve from a body BD toward a frame FMP. The bridge BG-4 may have a bent shape in which ridges are repeated from a body BD toward a frame FMP.

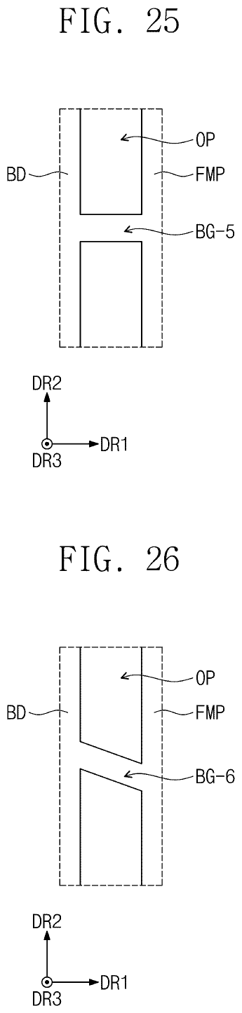

Referring to FIGS. 25 and 26, the bridge BG-5 may extend in a straight line from a body BD toward a frame FMP. The bridge BG-6 may obliquely extend from a body BD toward a frame FMP.

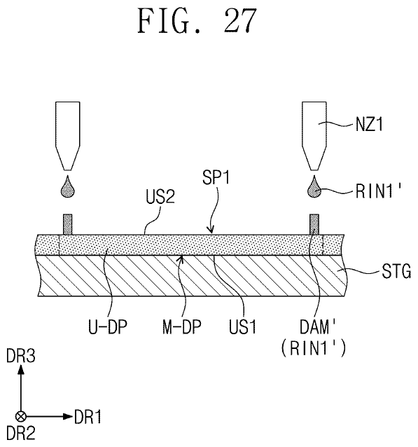

FIGS. 27 to 31 are views for explaining a method of manufacturing a display module according to an embodiment of the present disclosure.

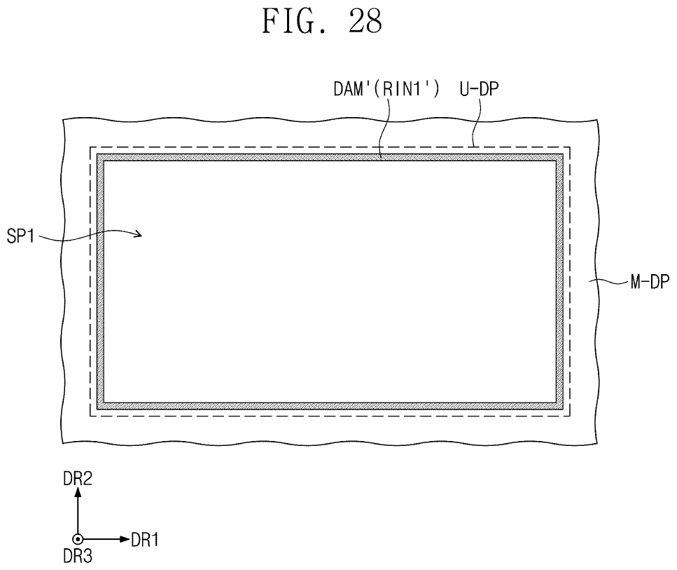

In FIGS. 27 and 29 to 31, a section of one unit panel U-DP of the mother panel M-DP is illustrated. FIG. 28 is a plan view of a dam DAM′ illustrated in FIG. 27.

Referring to FIGS. 27 and 28, the mother panel M-DP may be disposed on the stage STG, and a first nozzle NZ1 may be disposed over the mother panel M-DP. The above-described mask MK might not be used. A first resin RIN1′ may be disposed on the mother panel M-DP from the first nozzle NZ1. The first resin RIN1′ may be disposed in a quadrilateral closed loop shape on the mother panel M-DP. For example, the first nozzle NZ1 may move along the quadrilateral closed loop shape and may provide the first resin RIN1′ on the mother panel M-DP.

The dam DAM′ having a quadrilateral closed loop shape may be formed by the first resin RIN1′. A first space SP1 may be defined by the dam DAM′. The first space SP1 may substantially correspond to the first space SP1 of FIG. 10 defined by the removal of the above-described body BD. Accordingly, the first space SP1 defined by the dam DAM′ is assigned with the same reference numeral as that of the first space SP1 illustrated in FIG. 10.

The above-described dummy layer DUM may be formed by the first resin RIN1′, and for convenience of description, the dummy layer DUM is omitted in FIGS. 27 to 31.

The first resin RIN1′ may include an ultraviolet curable resin (hereinafter, referred to as the UV curable resin). In addition, the first resin RIN1′ may be black in color. Accordingly, the dam DAM′ may have a light blocking function and an impact absorbing function.

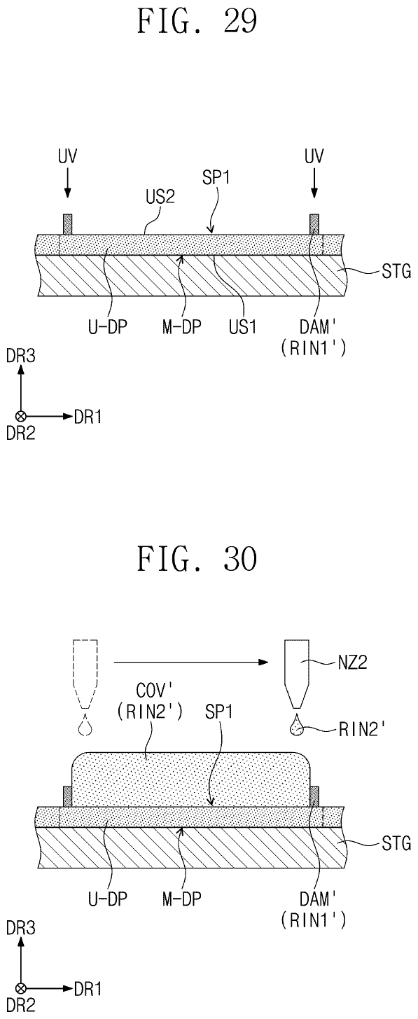

Referring to FIG. 29, the dam DAM′ may be cured by ultraviolet (UV) light. Because the UV curable resin does not shrink even though cured by the ultraviolet (UV) light, the thickness of the dam DAM′ may be maintained.

Referring to FIG. 30, a second resin RIN2′ may be disposed in the first space SP1 by a second nozzle NZ2. The second resin RIN2′ may have a height greater than that of the dam DAM′. For example, the second resin RIN2′ may be disposed on the mother panel M-DP so as to be thicker than the first resin RIN1′. A cover layer COV′ may be formed by the second resin RIN2′.

The second resin RIN2′ may include a material different from that of the first resin RIN1′. The second resin RIN2′ may include a thermosetting resin. The second resin RIN2′ may include the same material as the above-described first and second resins RIN1 and RIN2. Accordingly, the cover layer COV′ may have a heat radiating function, a light blocking function, an electromagnetic shielding function, and an impact absorbing function.

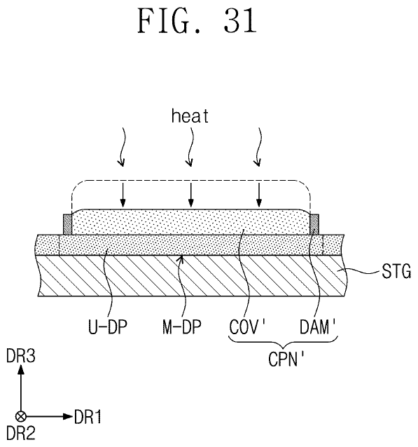

Referring to FIG. 31, the cover layer COV′ may be thermally cured. The cover layer COV′ may shrink during the thermal curing. The cover layer COV′ shrunk by the thermal curing may have a thickness similar to that of the dam DAM′. A cover panel CPN′ may be formed by the cured dam DAM′ and the cured cover layer COV′. Subsequent processes may be substantially the same as the processes described with reference to FIGS. 15 to 17. Accordingly, the display module including the cover panel CPN′ illustrated in FIG. 31 may be manufactured.

The dam DAM′ may have a light blocking function and an impact absorbing function, and the cover layer COV′ may additionally have a heat radiating function and an electromagnetic shielding function, in addition to the light blocking function and the impact absorbing function. Because the area of the cover layer COV′ is much larger than the area of the dam DAM′, the cover panel CPN′ may be substantially defined as a structure having a heat radiating function, a light blocking function, an electromagnetic shielding function, and an impact absorbing function.

In the embodiment of the present disclosure, the cover panel CPN′ may be manufactured by using the first resin RIN1′ and the second resin RIN2′ having different materials without the use of the mask MK.

According to the embodiments of the present disclosure, the mask does not have large openings and includes the bodies disposed therein. The bodies and the ribs of the frame are connected by the bridges. Accordingly, due to the bridges, the ribs of the frame might not be curved. Thus, a defect in the cover panels manufactured by the mask may be reduced.

While the present disclosure has been described with reference to embodiments thereof, it will be apparent to those of ordinary skill in the art that various changes and modifications may be made thereto without departing from the spirit and scope of the present disclosure.

What is claimed is:

1. An apparatus for manufacturing a display module, the apparatus comprising:
a stage; and
a mask disposed over the stage,
wherein the mask includes:
a body;
a frame surrounding the body; and
a plurality of bridges disposed between the body and the frame and extending from the body toward the frame, and
wherein a plurality of openings are defined between the bridges.

2. The apparatus of claim 1, wherein the bridges are disposed along an edge of the body.

3. The apparatus of claim 1, wherein the frame includes a plurality of dummy openings defined therein, and the dummy openings are disposed outward of both the bridges and the openings.

4. The apparatus of claim 3, wherein the dummy openings at least partially surround the bridges.

5. The apparatus of claim 1, wherein the body, the frame, and the bridges are integrally formed with each other.

6. The apparatus of claim 1, wherein each of the bridges has a width of 0.5 mm to 1.5 mm, inclusive.

7. The apparatus of claim 1, further comprising:
a mask frame surrounding the mask; and
a plurality of supports disposed on the stage, adjacent to an edge of a mother panel, and seated on an upper surface of the stage.

8. The apparatus of claim 7, wherein the mother panel includes:
a first surface;
a second surface opposite to the first surface;
a substrate disposed between the first surface and the second surface; and
a display element layer disposed on the substrate between the first surface and the second surface and facing the first surface and overlapping the body, and
wherein the first surface of the mother panel faces the stage, and the second surface of the mother panel faces the mask.

9. The apparatus of claim 1, wherein each of the bridges has a bent shape, a curved shape, and/or a trapezoidal shape from the body toward the frame.

10. The apparatus of claim 1, wherein each of the bridges extends in a straight line and/or an oblique line from the body toward the frame.

11. A method for manufacturing a display module, the method comprising:
placing a mother panel on a stage;
placing, on the mother panel, a mask including a body, a frame at least partially surrounding the body, and a plurality of bridges each extending from the body toward the frame, wherein the mask has openings defined between the bridges;
forming a plurality of dams by disposing a first resin in the openings;
removing the mask;
forming a cover layer by disposing a second resin in a first space defined by removal of the body and second spaces defined by removal of the bridges; and
forming a cover panel by curing the dams and the cover layer.

12. The method of claim 11, wherein the mother panel includes:
a first surface;
a second surface opposite to the first surface;
a substrate disposed between the first surface and the second surface; and
a display element layer disposed on the substrate between the first surface and the second surface and facing toward the first surface and overlapping the body,
wherein the first surface of the mother panel faces the stage, and the second surface of the mother panel faces the mask, and
wherein the cover panel is disposed on the second surface of the mother panel.

13. The method of claim 12, further comprising:
forming a plurality of dummy layers by additionally providing the first resin in a plurality of dummy openings defined in the frame and disposed outward of the bridges and the openings.

14. The method of claim 13, further comprising:
cutting the mother panel along a cutting line of the mother panel defined between the dummy layers and the cover layer by using a cutting tool disposed on the first surface of the mother panel.

15. The method of claim 13, wherein the bridges are arranged along an edge of the body, the dummy openings at least partially surround the bridges, and the body, the frame, and the bridges are integrally formed with one another.

16. The method of claim 12, wherein the first resin and the second resin include a same material.

17. The method of claim 12, wherein the first resin and the second resin are each thermally cured.

18. The method of claim 12, wherein the second resin has a viscosity of 1000 cps to 100000 cps.

19. The method of claim 12, wherein each of the bridges has a bent shape, a curved shape, and/or a trapezoidal shape from the body toward the frame.

20. A method for manufacturing a display module, the method comprising:
placing a mother panel on a stage;
forming a dam having a closed loop shape by disposing a first resin on the mother panel;
curing the dam using ultraviolet light;
forming a cover layer by disposing a second resin in a space defined by the dam, wherein the second resin is disposed to a height greater than a height of the dam; and
thermally curing the cover layer,
wherein the first resin includes a UV curable resin, and the second resin includes a thermosetting resin.
